(19) United States
(12) Patent Application Publication
(10) Pub. No.: US 2026/0018387 A1
(43) Pub. Date: Jan. 15, 2026

(54) COMPONENT FOR PLASMA PROCESSING APPARATUS AND METHOD OF PRODUCING COMPONENT

(71) Applicant: Tokyo Electron Limited, Tokyo (JP)

(72) Inventor: Kosuke MIZOI, Miyagi (JP)

(73) Assignee: Tokyo Electron Limited, Tokyo (JP)

(21) Appl. No.: 19/332,273

(22) Filed: Sep. 18, 2025

Related U.S. Application Data
(63) Continuation of application No. PCT/JP2024/008018, filed on Mar. 4, 2024.

(30) Foreign Application Priority Data
Mar. 28, 2023 (JP) 2023-050764

(51) Int. Cl. H01J 37/32; C23C 4/06

(52) U.S. Cl. CPC H01J 37/32495; C23C 4/06; H01J 37/32633; H01J 37/32834

(57) ABSTRACT

A component for plasma processing apparatus includes a base member and a thermal-sprayed film on a surface of the base member. The surface of the base member includes a main surface and a recess descending from the main surface of the base member at a position overlapping a distal edge portion of the thermal-sprayed film. The thermal-sprayed film includes a first thermal-sprayed film formed as a continuous film over the main surface of the base member and a part of a region inside the recess, and a second thermal-sprayed film including a material different from the first thermal-sprayed film, and being formed as a continuous film over the first thermal-sprayed film to cover the first thermal-sprayed film and over another part of the region inside the recess not covered by the first thermal-sprayed film.

### CROSS-REFERENCE TO RELATED APPLICATIONS

This application is a continuation application of International Application No. PCT/JP2024/008018, filed Mar. 4, 2024, which claims priority to Japanese Patent Application No. 2023-050764 filed Mar. 28, 2023. The contents of these applications are incorporated herein by reference in their entirety.

### BACKGROUND

### 1. Field of the Invention

The present invention relates to components for plasma processing apparatuses, and methods of producing components.

### 2. Description of the Related Art

A method of producing a component for a plasma processing apparatus, in which a coating film is formed on a component by atmospheric plasma spraying, is disclosed in Japanese Unexamined Patent Application Publication No. 2018-168474. In this method of producing a component, an intermediate layer and a coating film, such as thermal-sprayed films of yttrium oxide, are sequentially formed on an alumite film that constitutes an inner circumferential surface of a hole in a base member by atmospheric plasma spraying.

### SUMMARY

According to one aspect of the present disclosure, there is provided a component for a plasma processing apparatus. The component includes a base member and a thermal-sprayed film on a surface of the base member. The surface of the base member includes a main surface and a recess descending from the main surface of the base member at a position overlapping a distal edge portion of the thermal-sprayed film. The thermal-sprayed film includes a first thermal-sprayed film formed as a continuous film over the main surface of the base member and a part of a region inside the recess, and a second thermal-sprayed film including a material different from the first thermal-sprayed film, and being formed as a continuous film over the first thermal-sprayed film to cover the first thermal-sprayed film and over another part of the region inside the recess not covered by the first thermal-sprayed film.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a diagram schematically illustrating a plasma processing system including a plasma processing apparatus of the present disclosure;

FIG. 2 is a cross-sectional view illustrating an installation example of a baffle plate in a plasma processing chamber;

FIG. 3 is an enlarged cross-sectional view illustrating the vicinity of a portion of the baffle plate on which a distal edge portion of a thermal-sprayed film is formed;

FIG. 4A is a flowchart illustrating a first production method for a baffle plate, and FIG. 4B is a second production method for a baffle plate;

FIGS. 5A to 5D are explanatory diagrams schematically illustrating steps of the first production method for the baffle plate;

FIGS. 6A to 6D are explanatory diagrams schematically illustrating steps of the first production method for the baffle plate; and

FIG. 7 is an enlarged cross-sectional view illustrating the vicinity of a portion of the baffle plate according to a modification example, on which a distal edge portion of a thermal-sprayed film is formed.

### DETAILED DESCRIPTION

Hereinafter, embodiments for implementing the present disclosure will be described with reference to drawings. Throughout the drawings, the same or corresponding constituent components are designated by the same or corresponding reference symbols, and redundant description may be omitted.

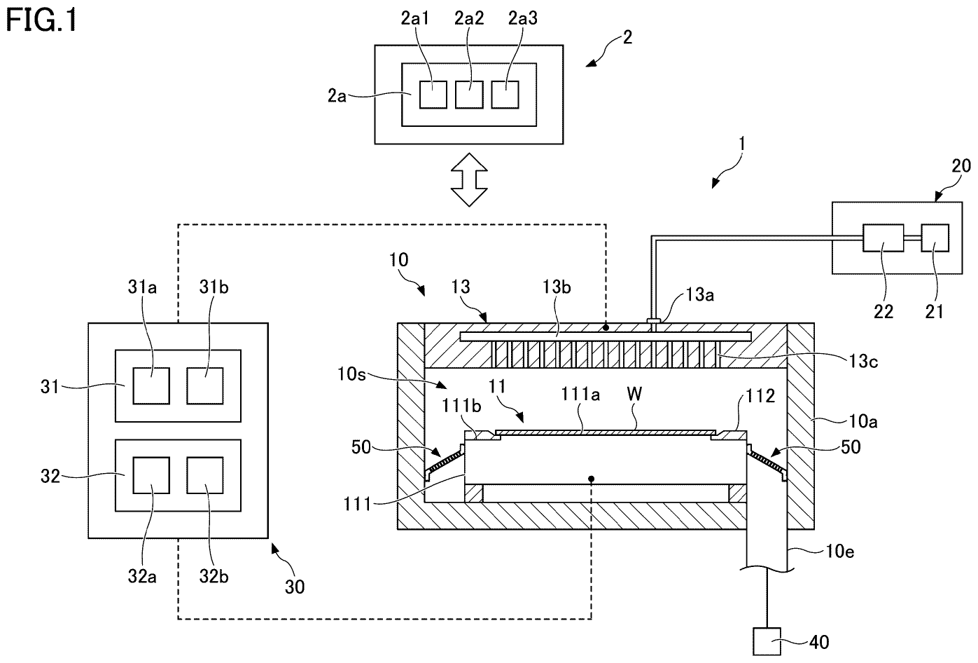

FIG. 1 is a diagram schematically illustrating a plasma processing system including the plasma processing apparatus of the present disclosure. First, a configuration example of the plasma processing system will be described with reference to FIG. 1 hereinafter.

The plasma processing system includes a capacitively coupled plasma processing apparatus 1 and a controller 2. The capacitively coupled plasma processing apparatus 1 includes a plasma processing chamber 10, a gas supply 20, a power supply 30, and an exhaust system 40. In addition, the plasma processing apparatus 1 includes a substrate support 11 and a gas feeder. The gas feeder is configured to feed a least one processing gas into the plasma processing chamber 10. The gas feeder includes a showerhead 13. The substrate support 11 is disposed inside the plasma processing chamber 10. The showerhead 13 is disposed above the substrate support 11. In one embodiment, the showerhead 13 constitutes at least part of a top portion (ceiling) of the plasma processing chamber 10. The plasma processing chamber 10 has a plasma processing space 10s defined by the showerhead 13, side walls 10a of the plasma processing chamber 10, and the substrate support 11. The plasma processing chamber 10 includes at least one gas supply port for supplying at least one processing gas to the plasma processing space 10s, and at least one gas exhaust hole 10e for exhausting the gas from the plasma processing space. The side wall 10a is grounded. The showerhead 13 and the substrate support 11 are electrically insulated from the housing of the plasma processing chamber 10.

The substrate support 11 includes a main body 111 and a ring assembly 112. The main body 111 includes a center region (substrate supporting surface) 111a for supporting a substrate (wafer) W, and an annular region (ring supporting surface) 111b for supporting a ring assembly 112. The annular region 111b of the main body 111 surrounds the center region 111a of the main body 111 in a plan view. The substrate W is disposed on the center region 111a of the main body 111, and the ring assembly 112 is disposed on the annular region 111b of the main body 111 to surround the substrate W on the center region 111a of the main body 111. In one embodiment, the main body 111 includes a stage and an electrostatic chuck. The stage includes a conductive member. The conductive member of the stage functions as a lower electrode. The electrostatic chuck is disposed on the stage. The upper surface of the electrostatic chuck constitutes the substrate supporting surface 111a. The ring assembly 112 includes one or more annular members. At least one annular member among the one or more annular members is an edge ring. Although it is not illustrated, the substrate support 11 may include a temperature-control module configured to adjust a temperature of the electrostatic chuck, the ring assembly 112, the substrate, or a combination of the foregoing to a target temperature. The temperature-control module may include a heater, a heat transfer medium, a path, or a combination of the foregoing. A heat transfer fluid, such as brine or a gas, flows through the path. Moreover, the substrate support 11 may include a heat-transfer gas supply configured to supply a heat transfer gas between the back surface of the substrate W and the substrate supporting surface 111a.

The showerhead 13 is configured to feed at least one processing gas from the gas supply 20 to the plasma processing space 10s. The showerhead 13 includes at least one gas supply port 13a, at least one gas diffusion chamber 13b, and multiple gas feeding holes 13c. A processing gas supplied to the gas supply port 13a is passed through the gas diffusion chamber 13b, and is fed into the plasma processing space 10s from the gas feeding holes 13c. Moreover, the showerhead 13 includes a conductive member. The conductive member of the showerhead 13 functions as an upper electrode. In addition to the showerhead 13, the gas feeder may include one or more side gas injectors (SGI) attached to one or more openings formed in the side walls 10a.

The gas supply 20 may include at least one gas source 21 and at least one flow rate regulator 22. In one embodiment, the gas supply 20 is configured to supply at least one processing gas from a corresponding gas source 21 to the showerhead 13 via a corresponding flow rate regulator 22. Each flow rate regulator 22 may include, for example, a mass-flow controller or a pressure-controlled flow rate regulator. Further, the gas supply 20 may include one or more flow rate modulation devices that modulate or pulse a flow rate of at least one processing gas.

The power supply 30 includes an RF power supply 31 coupled to the plasma processing chamber 10 via at least one impedance matching circuit. The RF power supply 31 is configured to supply at least one RF signal (RF power), such as a source RF signal and a bias RF signal, to the conductive member of the substrate support 11, or a conductive member of the showerhead 13, or both. Thus, at least one processing gas supplied to the plasma processing space 10s is formed into a plasma. The RF power supply 31 can therefore function as at least part of a plasma generator that is configured to form a plasma from one or more processing gases in the plasma processing chamber 10. Moreover, a bias potential is generated in the substrate W by supplying a bias RF signal to the conductive member of the substrate support 11, thereby attracting an ionic component in the formed plasma to the substrate W.

In one embodiment, the RF power supply 31 includes a first RF generator 31a and a second RF generator 31b. The first RF generator 31a is coupled to the conductive member of the substrate support 11, or the conductive member of the showerhead 13, or both via at least one impedance matching circuit, and is configured to generate a source RF signal (source RF power) for plasma formation. In one embodiment, the source RF signal has a frequency in the range of 13 MHz to 150 MHZ. In one embodiment, the first RF generator 31a may be configured to generate multiple source RF signals having different frequencies. The generated one or more source RF signals are supplied to the conductive member of the substrate support 11, or the conductive member of the showerhead 13, or both. The second RF generator 31b is coupled to the conductive member of the substrate support 11 via at least one impedance matching circuit, and is configured to generate a bias RF signal (bias RF power). In one embodiment, the bias RF signal has a lower frequency than the frequency of the source RF signal. In one embodiment, the bias RF signal has a frequency in the range of 400 kHz to 13.56 MHz. In one embodiment, the second RF generator 31b may be configured to generate multiple bias RF signals having different frequencies. The generated one or more bias RF signals are supplied to the conductive member of the substrate support 11. In various embodiments, the source RF signal, the bias RF signal, or both the source RF signal and the bias RF signal may pulsate.

Further, the power supply 30 may include a DC power supply 32 coupled to the plasma processing chamber 10. The DC power supply 32 includes a first DC generator 32a and a second DC generator 32b. In one embodiment, the first DC generator 32a is coupled to the conductive member of the substrate support 11, and is configured to generate a first DC signal. The generated first bias DC signal is applied to the conductive member of the substrate support 11. In one embodiment, the first DC signal may be applied to another electrode, such as an electrode in an electrostatic chuck. In one embodiment, the second DC generator 32b is coupled to the conductive member of the showerhead 13, and is configured to generate a second DC signal. The generated second DC signal is applied to the conductive member of the showerhead 13. In various embodiments, the first DC signal, the second DC signal, or both the first DC signal and the second DC signal may pulsate. The first and second DC generators 32a and 32b may be provided in addition to the RF power supply 31, or the first DC generator 32a may be provided instead of the second RF generator 31b.

The exhaust system 40 can be coupled to, for example, the gas exhaust hole 10e provided at the bottom of the plasma processing chamber 10. The exhaust system 40 may include a pressure regulating valve and a vacuum pump. The pressure in the plasma processing space 10s is adjusted by the pressure regulating valve. The vacuum pump may include a turbomolecular pump, a dry pump, or a combination of a turbomolecular pump and a dry pump.

The controller 2 processes computer-executable instructions that cause the plasma processing apparatus 1 to perform various steps described in the present disclosure. The controller 2 is configured to control each of constituent components of the plasma processing apparatus 1 to perform various steps described here. In one embodiment, a part of the controller 2, or the whole controller 2 may be included in the plasma processing apparatus 1. For example, the controller 2 may include a computer 2a. The computer 2a may include, for example, a processor (central processing unit (CPU)) 2a1, a storage 2a2, and a communication interface 2a3. The processor 2a1 can be configured to perform various control operations based on programs stored in the storage 2a2. The storage 2a2 may include a random access memory (RAM), a read only memory (ROM), a hard disk drive (HDD), a solid state drive (SSD), or any combination of the foregoing. The communication interface 2a3 may communicate with the plasma processing apparatus 1 via a communication circuit, such as a local area network (LAN) or the like. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The plasma processing apparatus 1 according to one embodiment includes one or more baffle plates 50 between the side wall 10a of the plasma processing chamber 10 and the substrate support 11 (main body 111). For example, the baffle plate 50 is disposed vertically above the gas exhaust hole 10e. Since the baffle plate 50 is disposed between the plasma processing space 10s and the gas exhaust hole 10e, the baffle plate 50 has a function of substantially homogeneously dispersing the gas, which is supplied into the plasma processing space 10s, in the outward direction from the periphery of the substrate W. Thus, the gas pressure around the substrate support 11 becomes even so that the plasma processing apparatus 1 can suppress unevenness in substrate processing. Further, the baffle plate 50 may be grounded via the side wall 10a. The grounded baffle plate 50 can close off the electric field in the plasma processing space 10s. Thus, the plasma processing apparatus 1 can minimize the plasma of the plasma processing space 10s entering the exhaust system 40, and can inhibit abnormal discharge in the exhaust system 40.

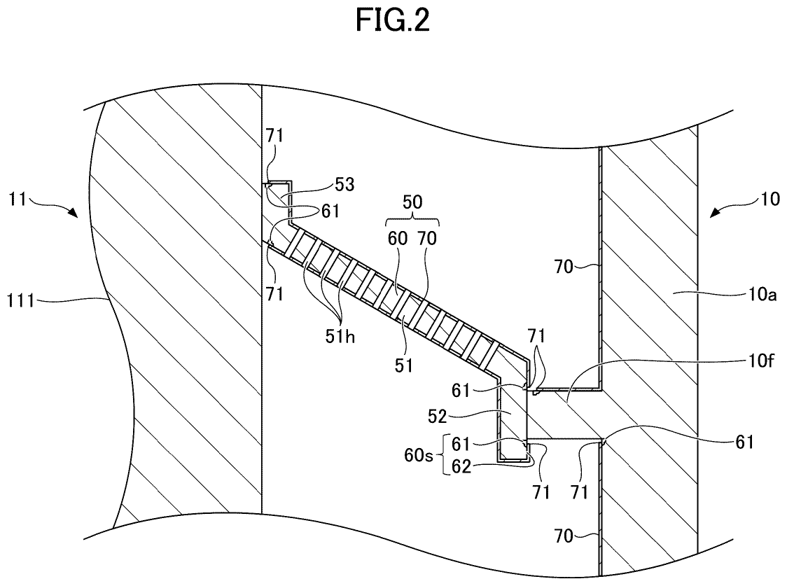

FIG. 2 is a cross-sectional view illustrating an installation example of the baffle plate 50 in the plasma processing chamber 10. As illustrated in FIG. 2, the baffle plate 50 according to one embodiment is fixed in a position inclined with respect to the horizontal direction and the vertical direction in the plasma processing chamber 10. The installation position of the baffle plate 50 is not limited to the inclined position. For example, the baffle plate 50 may be disposed to extend in the horizontal direction. Although it is not illustrated, the baffle plate 50 is formed to have an appropriate planar shape according to the planar shape of the side wall 10a of the plasma processing chamber 10 or the substrate support 11. For example, in the case where the plasma processing chamber 10 and the substrate support 11 have circular shapes, the baffle plate 50 can be formed in an arc shape, an annular shape, or the like.

The baffle plate 50 includes a main plate 51, an outer edge portion 52 located at a position away from the substrate support 11, and an inner edge portion 53 in contact with (or located at a position in the vicinity of) the substrate support 11. The outer edge portion 52 and the inner edge portion 53 are integrally connected to the main plate 51 extending in an inclined manner, and each of the outer edge portion 52 and the inner edge portion 53 is bent at an appropriate angle from the main plate 51 and extends in the vertical direction.

The baffle plate 50 is fixed by fixing the outer edge portion 52 to the side wall 10a, and fixing the inner edge portion 53 to the substrate support 11 so that the main plate 51 is arranged to block a gas exhaust path from the plasma processing space 10s to the gas exhaust hole 10e. The main plate 51 has multiple through holes 51h penetrating in the thickness direction. The through holes 51h allow the gas present on the upper side of the baffle plate 50 in the vertical direction to flow down toward the lower side of the baffle plate 50 in the vertical direction.

The outer edge portion 52 is attached to, for example, an attachment protrusion 10f projected from the inner surface of the side wall 10a by an appropriate fixing method. Moreover, the inner edge portion 53 is attached to the side surface of the substrate support 11 by an appropriate fixing method. The fixing method for the baffle plate 50 is not particularly limited. For example, screwing, welding, or the like can be employed.

The above baffle plate 50 is formed by coating a surface 60s of a plate-like base member 60 with a thermal-sprayed film 70. The thermal-sprayed film 70 is a coating for shielding the base member 60 from exposure to a plasma formed in the plasma processing chamber 10, and is a stack of multiple types of thermal-sprayed films, which will be described in detail later.

The base member 60 of the baffle plate 50 is formed in advance into a shape that can be disposed between the side wall 10a and the substrate support 11 by a processing method, such as injection molding, pressing, machining, or the like. The thickness of the base member 60 is not particularly limited. For example, the thickness can be set in the range of approximately 1 mm to approximately 10 mm. The base member 60 is formed of a material having conductivity. As the material of the base member 60, for example, a metal, such as aluminum, iron, copper, an alloy of the foregoing, or the like, can be used. The base member 60 of one embodiment is formed of aluminum. Moreover, an alumite film may be formed on the surface 60s of the base member 60 by anodizing (anodic oxidation). In this case, the thermal-sprayed film 70 can be deposited on the alumite film.

Further, the thermal-sprayed film 70 covers substantially the entire surface 60s (the upper surface, the lower surface, and the side surfaces) of the base member 60. FIG. 2 depicts the configuration in which the thermal-sprayed film 70 is not provided to the inner surface of each through hole 51h, but the thermal-sprayed film 70 may be formed on the inner surface of each through hole 51h.

However, the baffle plate 50 includes a region, in which the thermal-sprayed film 70 is not formed, at a connection part with the side wall 10a or a connection part with the substrate support 11 in order to connect the base member 60 to the side wall 10a, the substrate support 11, or the like. Therefore, a distal edge portion 71 of the thermal-sprayed film 70 is present in the base member 60, and the distal edge portion 71 is a boundary between a region covered with the thermal-sprayed film 70 and a region uncovered with the thermal-sprayed film 70.

For example, the distal edge portion 71 is provided at the position in the vicinity of the connection part of the baffle plate 50 with the side wall 10a or the substrate support 11, as illustrated in FIG. 2. The distal edge portion 71 may be provided at a portion of the base member 60 extending in a flat shape, or may be provided at a position in the vicinity of the bent portion of the base member 60. Moreover, the plasma processing apparatus 1 may include the thermal-sprayed film 70 on the inner surface (e.g., the side walls 10a) of the plasma processing chamber 10. Thus, the thermal-sprayed film 70 can be used as a protective shield for the plasma processing chamber 10. In the case where the plasma processing chamber 10 is covered with the thermal-sprayed film 70, the distal edge portion 71 of the thermal-sprayed film 70 is preferably set in the vicinity of an installation position of each component.

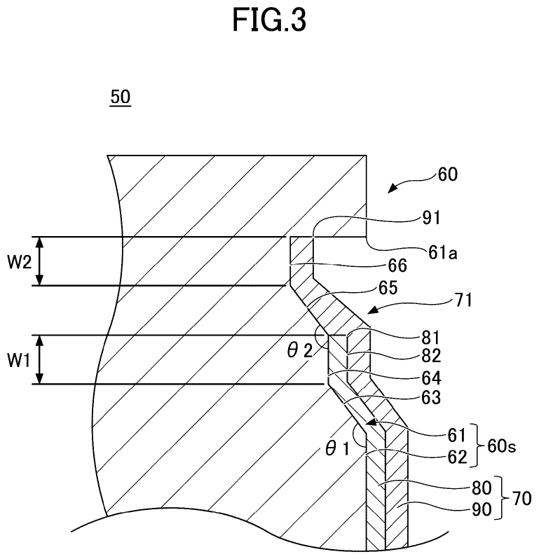

The base member 60 of the baffle plate 50 has a recess 61 at a position of the base member 60 corresponding to (overlapping) the distal edge portion 71. When the thermal-sprayed film 70 is formed, the distal edge portion 71 enters the recess 61. Thus, during formation of the thermal-sprayed film 70, the thermal-sprayed film 70 is inhibited from being formed on the opposite side of the surface 60s of the base member 60 across the recess 61 with respect to the thermal-sprayed film 70. A configuration of the thermal-sprayed film 70 and a configuration of the distal edge portion 71 will be described in detail hereinafter with reference to FIG. 3. FIG. 3 is an enlarged view illustrating the vicinity of the portion of the baffle plate 50, where the distal edge portion 71 of the thermal-sprayed film 70 is formed.

The thermal-sprayed film 70 includes a first thermal-sprayed film 80 and a second thermal-sprayed film 90. The first thermal-sprayed film 80 and the second thermal-sprayed film 90 are stacked in this order in the direction moving away from the surface 60s of the base member 60.

The first thermal-sprayed film 80 is formed of a material having a high withstand voltage (i.e., dielectric withstand voltage or breakdown voltage), and is set to have a thickness (thin film) to the extent that a breakage (crack or the like) is not caused by power applied to the base member 60. The material of the first thermal-sprayed film 80 may be a material that is appropriately bonded to yttrium, fluorine, oxygen, aluminum, or the like. Examples of the material of the first thermal-sprayed film 80 include yttrium fluoride (YF₃), yttrium oxide (Y₂O₃), yttrium oxyfluoride (YOF), yttrium aluminate (YAlO₃), aluminum oxide (Al₂O₃), and the like. Alternatively, as the material of the first thermal-sprayed film 80, zirconium oxide (ZrO₂), mullite (Al₆O₁₃Si₂), spinel (MgAl₂O₄), or the like may be used.

For the second thermal-sprayed film 90, a material having a lower withstand voltage than the withstand voltage of the first thermal-sprayed film 80, but has a higher plasma resistance than the plasma resistance of the first thermal-sprayed film 80 is preferably used. Examples of the material of the second thermal-sprayed film 90 include yttrium fluoride, yttrium oxyfluoride, and the like. In the case where the material of the second thermal-sprayed film 90 is a different material (different kind of material) from the first thermal-sprayed film 80, and, for example, yttrium fluoride is used for the first thermal-sprayed film 80, yttrium oxyfluoride can be used for the second thermal-sprayed film 90.

For formation of the thermal-sprayed film 70 (the first thermal-sprayed film 80 and the second thermal-sprayed film 90), thermal spraying known in the related art can be applied. In the thermal spraying, for example, while spraying a powder for thermal spraying in a spraying space by a carrier gas, such as an argon gas or the like, a plasma is formed in the spraying space, thereby forming a plasma jet in which the powder for thermal spraying is melted, and the plasma jet is sprayed onto the base member 60. During spraying the plasma jet, a nozzle of the plasma jet or the base member 60 is relatively moved, thereby forming a thermal-sprayed film within the sprayed region on the base member 60.

As described above, the recess 61 is provided at the position of the base member 60 overlapping the distal edge portion 71 of the thermal-sprayed film 70. The surface 60s of the base member 60 includes a main surface 62 extending in a flat shape, and the recess 61 descending from the main surface 62 at the position overlapping the distal edge portion of the thermal-sprayed film 70. In a plan view of the base member 60 and the thermal-sprayed film 70, the recess 61 is in the shape of a groove extending along the direction in which the distal edge portion 71 extends.

The recess 61 has an opening 61a at the same height position as the main surface 62 of the base member 60. Moreover, the inner wall of the recess 61 on the side of the portion coated with the thermal-sprayed film 70 is inclined with respect to the opening 61a, whereas the inner wall of the recess 61 on the side of the portion uncovered with the thermal-sprayed film 70 is perpendicular to the opening 61a.

The recess 61 has a stepped bottom surface (a first step surface 64 and a second step surface 66) from the opening 61a in the depth direction. The first step surface 64 and the second step surface 66 are formed in this order from the opening 61a in the depth direction. Moreover, the recess 61 has a first inclined surface 63 between the main surface 62 and the first step surface 64, and also a second inclined surface 65 between the first step surface 64 and the second step surface 66. Specifically, the first step surface 64 is continuous with the main surface 62 via the first inclined surface 63, thus the first step surface 64 is arranged at a deeper position than the main surface 62. The second step surface 66 is continuous with the first step surface 64 via the second inclined surface 65, thus the second step surface 66 is disposed at a deeper position than the first step surface.

The first step surface 64 and the second step surface 66 are formed substantially parallel to the extending direction of the main surface 62. The width W1 of the first step surface 64 is not particularly limited. For example, the width W1 is preferably set in the range of approximately 0.5 mm to approximately 5 mm. Similarly, the width W2 of the second step surface 66 is also not particularly limited. For example, the width W2 is preferably set in the range of approximately 0.5 mm to approximately 5 mm. In the example of FIG. 3, the width W1 of the first step surface 64 and the width W2 of the second step surface 66 are the same size, but the widths W1 and W2 may have mutually different sizes.

Further, the angle θ1 of the first inclined surface 63 with respect to the main surface 62 is preferably set, for example, in the range of approximately 105° to approximately 165°. Similarly, the angle θ2 of the second inclined surface 65 with respect to the first step surface 64 is preferably set, for example, in the range of approximately 105° to approximately 165°. By setting the angle θ1 of the first inclined surface 63 and the angle θ2 of the second inclined surface 65 in the above manner, it is possible to suppress an acute profile change of the recess 61. Thus, the thermal-sprayed film 70 can be prevented from being moved due to an acute profile change, which leads to exposure of the first thermal-sprayed film 80.

The thermal-sprayed film 70 is applied so as to enter the recess 61 having the main surface 62, the first inclined surface 63, the first step surface 64, the second inclined surface 65, and the second step surface 66 described above, thereby forming the distal edge portion 71 of the thermal-sprayed film 70.

Specifically, the first thermal-sprayed film 80 continuously covers the main surface 62, the first inclined surface 63, and the first step surface 64 of the base member 60. The first thermal-sprayed film 80 has a distal edge 81 at the boundary between the first step surface 64 and the second inclined surface 65. Since the distal edge 81 is positioned at the boundary between the first step surface 64 and the second inclined surface 65 as described above, the first thermal-sprayed film 80 can be desirably discontinued, and the second thermal-sprayed film 90 can be stably applied onto the second inclined surface 65 and the second step surface 66. In FIG. 3, the distal edge 81 of the first thermal-sprayed film 80 is formed to be perpendicular to the first step surface 64, but the distal edge 81 of the first thermal-sprayed film 80 may have an inclined shape where the thickness of the first thermal-sprayed film 80 gradually decreases.

On the other hand, the second thermal-sprayed film 90 covers the top (the surface 82) of the first thermal-sprayed film 80 formed on the main surface 62, the first inclined surface 63, and the first step surface 64 of the base member 60, and also continuously covers the second inclined surface 65 and the second step surface 66 exposed from the first thermal-sprayed film 80. More specifically, the second thermal-sprayed film 90 is formed in a manner such that the second thermal-sprayed film 90 extends parallel to the surface 82 of the first thermal-sprayed film 80 of the first step surface 64, and then extends from the distal edge 81 of the first thermal-sprayed film 80 to the second inclined surface 65, while being inclined. The distal edge 91 of the second thermal-sprayed film 90 is positioned at the opposite edge (the perpendicular inner wall of the recess 61) of the second step surface 66 to the edge continuous with the second inclined surface 65. Since the distal edge 91 of the second thermal-sprayed film 90 is positioned at the opposite edge of the second step surface 66, the first thermal-sprayed film 80 can be assuredly covered.

Thus, according to the thermal-sprayed film 70, the second thermal-sprayed film 90 can be desirably formed into the shape corresponding to the first inclined surface 63, the first step surface 64, the second inclined surface 65, and the second step surface 66 of the recess 61, and can encase the entire first thermal-sprayed film 80 between the base member 60 and the second thermal-sprayed film 90. Specifically, the thermal-sprayed film 70 can assuredly achieve an unexposed state of the first thermal-sprayed film 80 formed of a material having a high withstand voltage. Particularly in the recess 61, the first thermal-sprayed film 80 can be smoothly and continuously coated due to the first inclined surface 63, and the second thermal-sprayed film 90 can be smoothly and continuously coated due to the second inclined surface 65. Thus, it is possible to minimize a change in the thickness due to an acute profile change of the base member 60. Accordingly, the base member 60 can be more stably covered with the first thermal-sprayed film 80, and the first thermal-sprayed film 80 and the base member 60 are more stably covered with the second thermal-sprayed film 90.

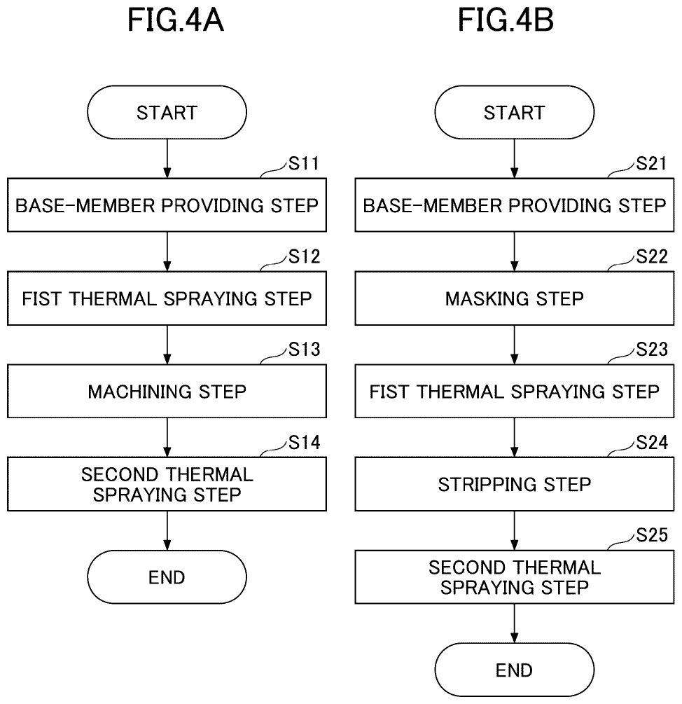

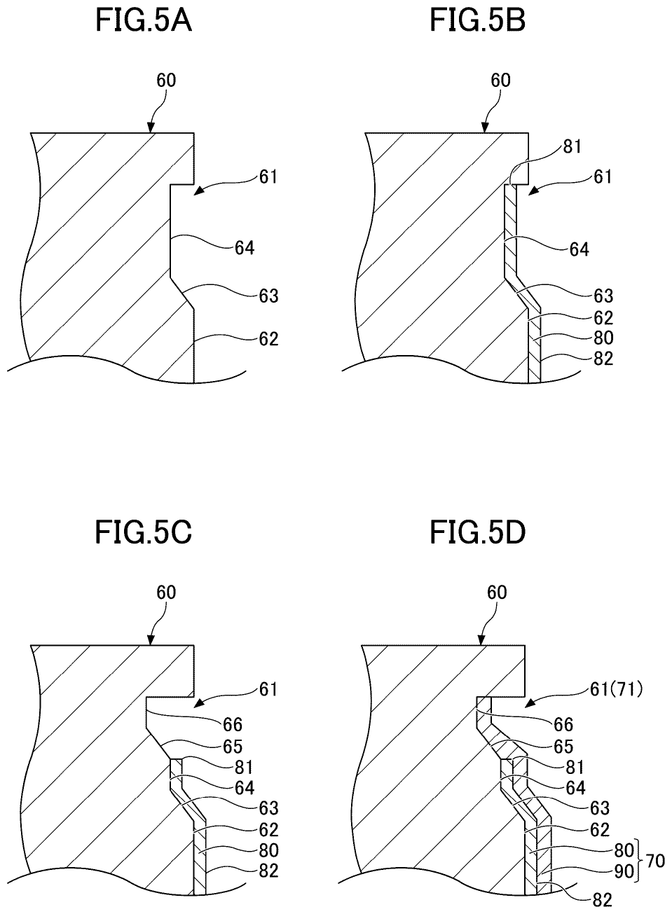

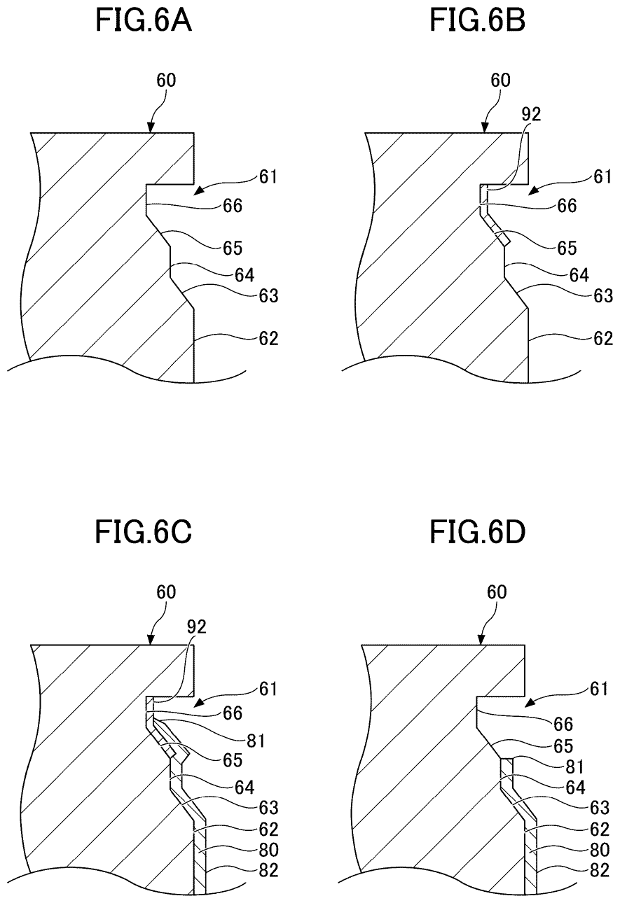

The baffle plate 50 (the component for the plasma processing apparatus) according to one component is basically formed as described above, and a method of producing the baffle plate 50 will be described with reference to FIGS. 4A to 6D. FIG. 4A is a flowchart of a first production method for the baffle plate 50. FIG. 4B is a flowchart of a second production method for the baffle plate 50. FIGS. 5A to 5D are explanatory diagrams schematically illustrating steps of the first production method for the baffle plate 50. FIGS. 6A to 6D are explanatory diagrams schematically illustrating steps of the second production method for the baffle plate 50.

### [First Production Method]

First, the first production method for the baffle plate 50 illustrated in FIG. 4A will be described. In the first production, a base-member providing step S11 (step of (A)), a first thermal spraying step S12 (step of (B)), a machining step S13 (step of (C)), and a second thermal spraying step S14 (step of (D)) are performed in this order.

At the base-member providing step S11, a base member 60 suitably used for the baffle plate 50 is prepared (provided). For example, at the base-member providing step S11, a manufacturer performs pressing of a plate material serving as an original material of the base member 60 to form the plate material into a shape corresponding to a main plate 51, an outer edge portion 52, and an inner edge portion 53. After pressing (or before pressing), the manufacturer performs machining on the plate material at an appropriate position (the position at which a distal edge portion 71 of a thermal-sprayed film 70 is to be formed) of the main surface 62 of the base member 60, thereby forming a recess 61.

However, as illustrated in FIG. 5A, the recess 61 of the base member 60 includes a first inclined surface 63 and a first step surface 64, but does not include a second inclined surface 65 nor a second step surface 66. Specifically, at the stage of the base-member providing step S11, the first step surface 64 is continuous in the recess 61 because a portion of the base member 60 is present at a position where a second inclined surface 65 and a second step surface 66 are to be formed.

Next, at the first thermal spraying step S12, a first thermal-sprayed film 80 is formed on the surface 60s of the base member 60 that is provided by the base-member providing step S11. The first thermal-sprayed film 80 is formed by appropriate thermal spraying described above so that the first thermal-sprayed film 80 continuously covers the main surface 62 of the base member 60 and the recess 61 as illustrated in FIG. 5B. Thus, in the recess 61, the first thermal-sprayed film 80 is, for example, in the state in which the first thermal-sprayed film 80 extends from the first inclined surface 63 to the opposite side of the inner wall of the recess 61 through the first step surface 64. The distal edge 81 of the first thermal-sprayed film 80 may be in contact with the inner wall as illustrated in FIG. 5B, or may be set slightly away from the inner wall.

At the machining step S13, machining is performed on the recess 61 of the base member 60 covered with the first thermal-sprayed film 80 by the first thermal spraying step S12, using a machining device that is not illustrated. At the machining step S13, the first step surface 64 and the first thermal-sprayed film 80 are integrally machined as illustrated in FIG. 5C. Thus, a second inclined surface 65 and a second step surface 66 are formed in the recess 61, and the first thermal-sprayed film 80 deposited on the area subjected to the machining is removed. Specifically, at the machining step S13, the distal edge 81 of the first thermal-sprayed film 80 is moved at the boundary between the first step surface 64 and the second inclined surface 65, and the base member 60 in which the second inclined surface 65 and the second step surface 66 are exposed from the first thermal-sprayed film 80 is formed.

At the final second thermal spraying step S14, the base member 60 after the machining step S13 is covered with a second thermal-sprayed film 90. The second thermal-sprayed film 90 is formed by appropriate thermal spraying described above in a manner such that the second thermal-sprayed film 90 continuously covers the surface 82 of the first thermal-sprayed film 80, and the second inclined surface 65 and second step surface 66 in the recess 61, as illustrated in FIG. 5D. Thus, according to the first production method, the thermal-sprayed film 70, with which the entire bottom surface of the recess 61 is covered with second thermal-sprayed film 90, and the first thermal-sprayed film 80 is assuredly unexposed at the distal edge portion 71, can be obtained.

### [Second Production Method]

Next, a second production method for the baffle plate 50 illustrated in FIG. 4B will be described. In the second production method, a base-member providing step 21 (step of (A)), a masking step S22 (step of (E)), a first thermal spraying step S23 (step of (B)), a stripping step S24 (step of (C)), and a second thermal spraying step S25 (step of (D)) are performed in this order.

At the base-member providing step S21, a base member 60 suitably used for the baffle plate 50 is provided. However, a recess 61 of the base member 60 used in the second production method includes a first inclined surface 63, a first step surface 64, a second inclined surface 65, and a second step surface 66, as illustrated in FIG. 6A.

At a subsequent masking step S22, the second inclined surface 65 and second step surface 66 of the recess 61 are covered with a mask 92 as illustrated in FIG. 6B. As the mask 92, for example, a member having a width matched with the widths of the second inclined surface 65 and second step surface 66, and having an adhesive layer on one surface can be used. Further, the mask 92 has a resistance against the first thermal-sprayed film 80 so that the mask is not dissolved by the first thermal-sprayed film 80 at the first thermal spraying step S23. Thus, the base member 60 after the masking step S22 is in the state in which the main surface 62, the first inclined surface 63, and the first step surface 64 are exposed from the mask 92.

At the first thermal spraying step S23, a first thermal-sprayed film 80 is formed on the surface 60s of the base member 60 after the masking step S22. The first thermal-sprayed film 80 is formed in a manner such that the first thermal-sprayed film 80 extends over the main surface 62, the first inclined surface 63, and the first step surface 64 of the base member 60, and further extends to a position in the middle of the mask 92, as illustrated in FIG. 6C. The mask 92 has a sufficient width, and therefore the distal edge 81 of the first thermal-sprayed film 80 can be readily positioned on the mask 92 even in the case where the spray range of thermal spraying is not stabilized.

At the subsequent stripping step S24, the mask 92 is stripped from the base member 60 on which the first thermal-sprayed film 80 is formed by the first thermal spraying step S23. As illustrated in FIG. 6D, at the stripping step, the first thermal-sprayed film 80 applied on the upper surface of the mask 92 is also stripped off together with the mask 92. Therefore, the base member 60 after stripping of the mask 92 is in a state in which the main surface 62, the first inclined surface 63, and the first step surface 64 are covered with first thermal-sprayed film 80, whereas the second inclined surface 65 and the second step surface 66 are exposed from the first thermal-sprayed film 80.

Finally, at the second thermal spraying step S25, similarly to the second thermal spraying step S14 of the first production method, a second thermal-sprayed film 90 is formed. Thus, the second thermal-sprayed film 90 is formed to continuously cover the first thermal-sprayed film 80, and the second inclined surface 65 and second step surface 66 in the recess 61 (see also FIG. 5D). As described above, the thermal-sprayed film 70, with which the entire bottom surface of the recess 61 is covered with second thermal-sprayed film 90, and the first thermal-sprayed film 80 is assuredly unexposed at the distal edge portion 71, can be obtained also in the second production method.

As described above, according to the baffle plate 50, which is the component for the plasma processing apparatus 1, and the production method for the baffle plate 50, the distal edge portion 71 at which the first thermal-sprayed film 80 is unexposed by being covered with the second thermal-sprayed film 90 is formed in the recess 61 of the base member 60. Thus, the baffle plate 50 can resist high voltage with the first thermal-sprayed film 80, and can minimize damage to the thermal-sprayed film 70 caused by a plasma owing to the second thermal-sprayed film 90. Specifically, the second thermal-sprayed film 90 has a high resistance against a plasma and covers the entire first thermal-sprayed film 80, and therefore the plasma is inhibited from reaching the first thermal-sprayed film 80. As a result, the baffle plate 50 can avoid damage to the first thermal-sprayed film 80 having a high withstand voltage, and can maintain the form of the thermal-sprayed film 70.

Since the baffle plate 50 has the first step surface 64 and the second step surface 66 in the recess 61, the range covered with the first thermal-sprayed film 80 and the range covered with the second thermal-sprayed film 90 can be appropriately separated. Therefore, covering of the first thermal-sprayed film 80 with the second thermal-sprayed film 90 can be more stably performed. Further, since the baffle plate 50 has the first inclined surface 63 and the second inclined surface 65 in the recess 61, the smooth first thermal-sprayed film 80 and the smooth second thermal-sprayed film 90 can be formed. As a result, the thickness of the first thermal-sprayed film 80 or the thickness of the second thermal-sprayed film 90 are not drastically changed, and the continuity of the first thermal-sprayed film 80 and the second thermal-sprayed film 90 can be ensured.

The baffle plate 50 and the production method for the baffle plate 50 are not limited to the above embodiment, and various modifications can be made. For example, the component for the plasma processing apparatus 1 is not limited to the baffle plate 50, and can be applied for various components that include thermal-sprayed films 70. Examples of such a component include a shutter that blocks a plasma inside the plasma processing chamber 10, and a shield member formed on the inner surface of the plasma processing chamber 10.

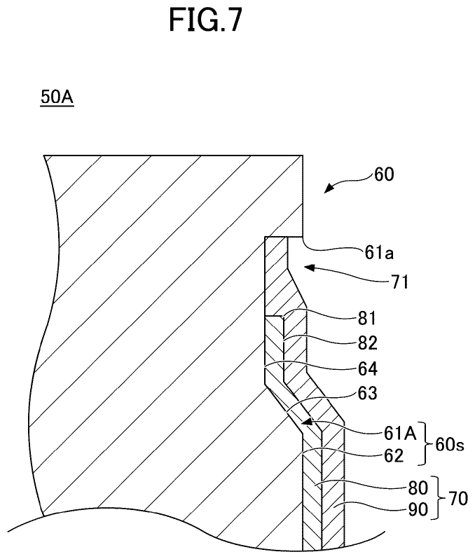

FIG. 7 is a cross-sectional view illustrating a distal edge portion 71 of a thermal-sprayed film 70 of a baffle plate 50A according to the modification example. As illustrated in FIG. 7, the baffle plate 50A is different from the baffle plate 50 of the above embodiment in that a recess 61A has a first step surface 64, but not a second step surface 66. Even in this case, the first thermal-sprayed film 80 covers the first step surface 64 up to the middle position of the first step surface 64, and the first thermal-sprayed film 80 and the exposed region of the first step surface 64 can be covered with the second thermal-sprayed film 90.

For example, the same method as the second production method is applied for the baffle plate 50A, and a mask 92 is provided at a portion (a portion in the vicinity of the inner wall on the opposite side of the first inclined surface 63) of the first step surface 64 of the recess 61A at the masking step S22. Then, the subsequent first thermal spraying step S23 is performed in the state in which the mask 92 is provided, thereby forming a first thermal-sprayed film 80 on the first step surface 64 and the mask 92. Further, the mask 92 is stripped from the first step surface 64 at the stripping step S24, thereby forming a portion of the first step surface 64 covered with the first thermal-sprayed film 80, and a portion of the first step surface 64 that is not covered with first thermal-sprayed film 80. Accordingly, as the second thermal spraying step S25 is performed last, a second thermal-sprayed film 90 can be deposited to extend continuously over the first thermal-sprayed film 80 and the first step surface 64.

Even in this case, the second thermal-sprayed film 90 can assuredly achieve an unexposed state of the first thermal-sprayed film 80. Accordingly, the thermal-sprayed film 70 can inhibit the first thermal-sprayed film 80 from being peeled off by a plasma formed in the plasma processing space 10s. Thus, the plasma processing apparatus 1 can inhibit contamination of the plasma processing space 10s due to peeling of the first thermal-sprayed film 80 from the baffle plate 50, and can desirably perform plasma processing of substrates W.

As described above, according to one aspect of the present disclosure, damage to a thermal-sprayed film caused by a plasma can be minimized.

The embodiment disclosed above includes, for example, the following embodiments.

### [Clause 1]

A component for a plasma processing apparatus, the component includes: a base member; and a thermal-sprayed film on a surface of the base member. The surface of the base member includes a main surface and a recess, the recess descending from the main surface of the base member at a position overlapping a distal edge portion of the thermal-sprayed film. The thermal-sprayed film includes a first thermal-sprayed film formed as a continuous film over the main surface of the base member and a part of a region inside the recess, and a second thermal-sprayed film including a material different from the first thermal-sprayed film, and being formed as a continuous film over the first thermal-sprayed film and the other part of the region inside the recess, thereby covering the first thermal-sprayed film.

### [Clause 2]

In the component for the plasma processing apparatus according to Clause 1, the recess includes a first step surface and a second step surface in order from an opening of the recess in a depth direction of the recess, the first thermal-sprayed film is formed to cover from the main surface of the base member to the first step surface, and the second thermal-sprayed film is formed to cover from the first thermal-sprayed film to the second step surface.

### [Clause 3]

In the component for the plasma processing apparatus according to Clause 2, the base member includes a first inclined surface between the main surface of the base member and the first step surface, and a second inclined surface between the first step surface and the second step surface, the first thermal-sprayed film is formed on the main surface of the base member, the first inclined surface, and the first step surface, and the second thermal-sprayed film is formed on the first thermal-sprayed film, the second inclined surface, and the second step surface.

### [Clause 4]

In the component for the plasma processing apparatus according to Clause 3, the first inclined surface is inclined at any angle in a range of 105° to 165° with respect to the main surface of the base member, and the second inclined surface is inclined at any angle in a range of 105° to 165° with respect to the first step surface.

### [Clause 5]

In the component for the plasma processing apparatus according to Clause 3 or 4, a distal edge of the first thermal-sprayed film is positioned at a boundary between the first step surface and the second inclined surface.

### [Clause 6]

In the component for the plasma processing apparatus according to any one of Clauses 3 to 5, a distal edge of the second thermal-sprayed film is positioned at an edge of the second step surface opposite to an edge of the second step surface continuous with the second inclined surface.

### [Clause 7]

In the component for the plasma processing apparatus according to any one of Clauses 1 to 6, the first thermal-sprayed film is formed of a material having a higher withstand voltage than a withstand voltage of the second thermal-sprayed film, and the second thermal-sprayed film is formed of a material having a higher plasma resistance than a plasma resistance of the first thermal-sprayed film.

### [Clause 8]

In the component for the plasma processing apparatus according to Clause 7, the first thermal-sprayed film includes at least one selected from the group consisting of yttrium fluoride, yttrium oxide, yttrium oxyfluoride, yttrium aluminate, and aluminum oxide, and the second thermal-sprayed film includes yttrium fluoride, yttrium oxyfluoride, or both yttrium fluoride and yttrium oxyfluoride.

### [Clause 9]

In the component for the plasma processing apparatus according to any one of Clauses 1 to 8, the component is at least one selected from the group consisting of a baffle plate disposed in a gas exhaust path inside a plasma processing chamber, a shutter configured to block a plasma inside the plasma processing chamber, and a shield formed on an inner surface of the plasma processing chamber.

### [Clause 10]

A method of producing a component for a plasma processing apparatus, the component including a base member and a thermal-sprayed film on a surface of the base member, the method includes:
(A) providing the base member in which the surface of the base member includes a main surface and a recess descending from the main surface of the base member at a position overlapping a distal edge portion of the thermal-sprayed film;
(B) after (A), forming a first thermal-sprayed film as a continuous film over the main surface of the base member and the recess;
(C) after (B), processing the recess to strip a part of the first thermal-sprayed film inside the recess; and
(D) after (C), forming a second thermal-sprayed film, which includes a different material from the first thermal-sprayed film, as a continuous film over the first thermal-sprayed film and a region of the inner area of the recess from which the first thermal-sprayed film is stripped, thereby covering the first thermal-sprayed film with the second thermal-sprayed film.

### [Clause 11]

In the method of producing the component according to Clause 10, in (A), the providing includes providing of the base member including a first step surface at a bottom surface of the recess,
in (B), the forming includes forming of the first thermal-sprayed film in a range from the main surface of the base member to the first step surface,
in (C), the processing includes machining of the first thermal-sprayed film and the first step surface to form a second step surface at a position deeper than the first step surface with respect to a direction from an opening of the recess in a depth direction of the recess, and
in (D), the forming includes forming of the second thermal-sprayed film in a range from the first thermal-sprayed film to the second step surface.

### [Clause 12]

In the method of producing the component according to Clause 11,
in (A), the providing includes providing of the base member including a first inclined surface between the main surface of the base member and the first step surface,
in (B), the forming includes covering of the main surface of the base member, the first inclined surface, and the first step surface with the first thermal-sprayed film,
in (C), the processing includes machining of the recess to form a second inclined surface between the first step surface and the second step surface, and
in (D), the forming includes covering of the first thermal-sprayed film, the second inclined surface, and the second step surface with the second thermal-sprayed film.

### [Clause 13]

The method of producing the component according to Clause 10, further includes: (E), between (A) and (B), forming a mask on a second step surface,
wherein, in (A), the providing includes providing of the base member including a first step surface and the second step surface in order from an opening of the recess in a depth direction of the recess,
in (B), the forming includes covering of the main surface of the base member, the first step surface, and the mask with the first thermal-sprayed film,
in (C), the processing includes stripping of the mask and the first thermal-sprayed film formed on the mask to expose the second step surface, and
in (D), the forming includes covering of the first thermal-sprayed film and the second step surface with the second thermal-sprayed film.

### [Clause 14]

In the method of producing the component according to Clause 13,
in (A), the providing includes providing of the base member including a first inclined surface between the main surface of the base member and the first step surface, and a second inclined surface between the first step surface and the second step surface,
in (E), the forming includes covering of the second step surface and the second inclined surface with the mask,
in (B), the forming includes covering of the main surface of the base member, the first inclined surface, the first step surface, and the mask with the first thermal-sprayed film,
in (C), the processing includes stripping of the mask to expose the second step surface and the second inclined surface, and
in (D), the forming includes covering of the first thermal-sprayed film, the second inclined surface, and the second step surface with the second thermal-sprayed film.

The component for the plasma processing apparatus and the production method according to the embodiments disclosed herein are all illustrative and non-restrictive in all aspects. The embodiments can be modified and improved in various forms without departing from the scope and spirit of the appended claims. The features described in the above embodiments may be implemented through another configuration, or may be combined with one another, provided that no inconsistency is caused.

The plasma processing apparatus of the present disclosure can be applied for any type of apparatuses of atomic layer deposition (ALD) devices, capacitively coupled plasma (CCP), inductively coupled plasma (ICP), radial line slot antenna (RLSA), electron cyclotron resonance plasma (ECR), and helicon wave plasma (HWP).

What is claimed is:

1. A component for a plasma processing apparatus, the component comprising:
a base member; and
a thermal-sprayed film on a surface of the base member,
the surface of the base member including a main surface and a recess, the recess descending from the main surface of the base member at a position overlapping a distal edge portion of the thermal-sprayed film,
the thermal-sprayed film including:
a first thermal-sprayed film formed as a continuous film over the main surface of the base member and a part of a region inside the recess, and
a second thermal-sprayed film including a material different from the first thermal-sprayed film, and the second thermal-sprayed film being formed as a continuous film over the first thermal-sprayed film to cover the first thermal-sprayed film and over another part of the region inside the recess not covered by the first thermal-sprayed film.

2. The component for the plasma processing apparatus according to claim 1,
wherein the recess includes a first step surface and a second step surface, the first step surface being closer to an opening of the recess than the second step surface in a depth direction of the recess,
the first thermal-sprayed film is formed to cover from the main surface of the base member to the first step surface, and
the second thermal-sprayed film is formed to cover from the first thermal-sprayed film to the second step surface.

3. The component for the plasma processing apparatus according to claim 2,
wherein the base member includes a first inclined surface between the main surface of the base member and the first step surface, and a second inclined surface between the first step surface and the second step surface,
the first thermal-sprayed film is formed on the main surface of the base member, the first inclined surface, and the first step surface, and
the second thermal-sprayed film is formed on the first thermal-sprayed film, the second inclined surface, and the second step surface.

4. The component for the plasma processing apparatus according to claim 3,
wherein the first inclined surface is inclined at any angle in a range of 105° to 165° with respect to the main surface of the base member, and
the second inclined surface is inclined at any angle in a range of 105° to 165° with respect to the first step surface.

5. The component for the plasma processing apparatus according to claim 3,
wherein a distal edge of the first thermal-sprayed film is positioned at a boundary between the first step surface and the second inclined surface.

6. The component for the plasma processing apparatus according to claim 3,
wherein a distal edge of the second thermal-sprayed film is positioned at an edge of the second step surface opposite to an edge of the second step surface continuous with the second inclined surface.

7. The component for the plasma processing apparatus according to claim 1,
wherein the first thermal-sprayed film is formed of a material having a higher withstand voltage than a withstand voltage of the second thermal-sprayed film, and
the second thermal-sprayed film is formed of a material having a higher plasma resistance than a plasma resistance of the first thermal-sprayed film.

8. The component for the plasma processing apparatus according to claim 7,
wherein the first thermal-sprayed film includes at least one selected from the group consisting of yttrium fluoride, yttrium oxide, yttrium oxyfluoride, yttrium aluminate, and aluminum oxide, and
the second thermal-sprayed film includes yttrium fluoride, yttrium oxyfluoride, or both yttrium fluoride and yttrium oxyfluoride.

9. The component for the plasma processing apparatus according to claim 1,
wherein the component is at least one selected from the group comprising of a baffle plate disposed in a gas exhaust path inside a plasma processing chamber, a shutter configured to block a plasma inside the plasma processing chamber, and a shield formed on an inner surface of the plasma processing chamber.

10. A method of producing a component, method comprising:
(A) providing a base member in which a surface of the base member includes a main surface and a recess descending from the main surface of the base member at a position overlapping a distal edge portion of the thermal-sprayed film;
(B) after (A), forming a first thermal-sprayed film as a continuous film over the main surface of the base member and the recess;
(C) after (B), processing the recess to strip a part of the first thermal-sprayed film inside the recess; and
(D) after (C), forming a second thermal-sprayed film, which includes a different material from the first thermal-sprayed film, the second thermal-sprayed film being formed as a continuous film over the first thermal-sprayed film to cover the first thermal-sprayed film and over a region inside the recess from which the first thermal-sprayed film has been stripped.

11. The method of producing the component according to claim 10,
wherein in (A), the providing includes providing of the base member including a first step surface at a bottom surface of the recess,
in (B), the forming includes forming of the first thermal-sprayed film in a range from the main surface of the base member to the first step surface,
in (C), the processing includes machining of the first thermal-sprayed film and the first step surface to form a second step surface at a position deeper than the first step surface with respect to a direction from an opening of the recess in a depth direction of the recess, and
in (D), the forming includes forming of the second thermal-sprayed film in a range from the first thermal-sprayed film to the second step surface.

12. The method of producing the component according to claim 11,
wherein, in (A), the providing includes providing of the base member including a first inclined surface between the main surface of the base member and the first step surface,
in (B), the forming includes covering of the main surface of the base member, the first inclined surface, and the first step surface with the first thermal-sprayed film,
in (C), the processing includes machining of the recess to form a second inclined surface between the first step surface and the second step surface, and
in (D), the forming includes covering of the first thermal-sprayed film, the second inclined surface, and the second step surface with the second thermal-sprayed film.

13. The method of producing the component according to claim 10, further comprising:
(E), between (A) and (B), forming a mask on a second step surface,
wherein, in (A), the providing includes providing of the base member including a first step surface and the second step surface, the first step surface being closer to an opening of the recess than the second step surface in a depth direction of the recess,
in (B), the forming includes covering of the main surface of the base member, the first step surface, and the mask with the first thermal-sprayed film,
in (C), the processing includes stripping of the mask and the first thermal-sprayed film formed on the mask to expose the second step surface, and
in (D), the forming includes covering of the first thermal-sprayed film and the second step surface with the second thermal-sprayed film.

14. The method of producing the component according to claim 13,
wherein, in (A), the providing includes providing of the base member including a first inclined surface between the main surface of the base member and the first step surface, and a second inclined surface between the first step surface and the second step surface,
in (E), the forming includes covering of the second step surface and the second inclined surface with the mask,
in (B), the forming includes covering of the main surface of the base member, the first inclined surface, the first step surface, and the mask with the first thermal-sprayed film,
in (C), the processing includes stripping of the mask to expose the second step surface and the second inclined surface, and
in (D), the forming includes covering of the first thermal-sprayed film, the second inclined surface, and the second step surface with the second thermal-sprayed film.

15. A plasma processing apparatus comprising:
a plasma processing chamber having a side wall and a gas exhaust hole;
a substrate support disposed inside the plasma processing chamber;
a gas supply configured to supply at least one processing gas into the plasma processing chamber;
a power supply configured to supply RF power to form a plasma from the at least one processing gas; and
a baffle plate disposed between the side wall of the plasma processing chamber and the substrate support,
wherein the baffle plate includes a base member and a thermal-sprayed film on a surface of the base member,
the surface of the base member includes a main surface and a recess descending from the main surface of the base member at a position overlapping a distal edge portion of the thermal-sprayed film,
the thermal-sprayed film includes:
a first thermal-sprayed film formed as a continuous film over the main surface of the base member and a part of a region inside the recess; and
a second thermal-sprayed film including a material different from the first thermal-sprayed film, and the second thermal-sprayed film being formed as a continuous film over the first thermal-sprayed film and over another part of the region inside the recess not covered by the first thermal-sprayed film.

16. The plasma processing apparatus according to claim 15, wherein the recess includes a first step surface and a second step surface,
the first thermal-sprayed film continuously covers the main surface and the first step surface, and
the second thermal-sprayed film continuously covers the first thermal-sprayed film, the second step surface, and a surface between the first step surface and the second step surface.

17. The plasma processing apparatus according to claim 15, wherein the baffle plate is disposed vertically above the gas exhaust hole and is inclined with respect to a horizontal direction.

18. The plasma processing apparatus according to claim 15, further comprising:
a showerhead disposed above the substrate support, the showerhead including a conductive member functioning as an upper electrode,
wherein the substrate support includes a conductive member functioning as a lower electrode.

19. The plasma processing apparatus according to claim 15, wherein the base member of the baffle plate is formed of aluminum, and an alumite film is formed on the surface of the base member between the base member and the thermal-sprayed film.

20. The plasma processing apparatus according to claim 15, wherein the first thermal-sprayed film includes yttrium oxide, and the second thermal-sprayed film includes yttrium oxyfluoride.
